(19) United States
(12) Patent Application Publication
(10) Pub. No.: US 2018/0297168 A1
(43) Pub. Date: Oct. 18, 2018

(54) SEMICONDUCTOR WAFER PROCESSING METHOD

(71) Applicant: SUMCO CORPORATION, Tokyo (JP)

(72) Inventors: Toshiyuki TANAKA, Saga (JP); Yasuyuki HASHIMOTO, Saga (JP)

(73) Assignee: SUMCO CORPORATION, Tokyo (JP)

(21) Appl. No.: 15/769,637

(22) PCT Filed: Oct. 3, 2016
(86) PCT No.: PCT/JP2016/079247

§ 371 Date: Apr. 19, 2018

(30) Foreign Application Priority Data
Oct. 20, 2015 (JP) 2015-206066

(51) Int. Cl. B24B 7/04; B24B 27/06; B24B 7/22; H01L 21/304

(52) U.S. Cl. CPC B24B 7/04; H01L 21/304; B24B 7/22; B24B 27/06

(57) ABSTRACT

Disclosed is a semiconductor wafer processing method wherein, a thin disc-like wafer is manufactured by slicing a semiconductor single crystal ingot (slicing step), a planarized coating layer is formed by applying a curable material to the whole first surface of the wafer (coating layer forming step), and the coating layer is cured (coating layer curing step). A wafer second surface on the reverse side of the first surface is flatly grind by means of a grinding apparatus, the coating layer is removed from the first surface of the wafer. Furthermore, the first surface of the wafer is flatly ground by means of the grinding apparatus. The surface height of the first surface of the wafer after the slicing step and before the coating layer forming step is subjected to frequency analysis, and the coating layer forming step and the coating layer curing step are repeated a plurality of times.

### TECHNICAL FIELD

The present invention relates to a method of processing a semiconductor wafer. In particular, the present invention relates to a processing method for planarizing a surface of the semiconductor wafer. This international application is based upon and claims the benefit of priority from prior Japanese Patent application No. 206066 (P2015-206066) filed on Oct. 20, 2015, the entire contents of Japanese Patent Application No. 2015-206066 is incorporated herein by reference.

### BACKGROUND ART

In conventional semiconductor wafers, planarization of a surface of the wafer has been required for forming fine patterns by means of photomechanical process. In particular, surface waving called “nanotopography” is a concavity and convexity formed on a wafer surface of which a space wave long component is approximately 0.2 mm to approximately 20 mm, and there has recently been proposed a technology for improving a flatness of semiconductor wafers by reducing such topography. As such a planarizing processing method of wafer, there has been disclosed a manufacturing method of wafer, wherein: a thin disc-like wafer is manufactured by slicing a single crystal ingot; a curable material is applied to a first surface of this wafer and the curable material applied to the first surface of the wafer is formed to be flat; the wafer is mounted on a wafer holding means so that the flat face of the curable material is in contact with the wafer holding means after this curable material is cured, and then a second surface on a reverse side of the first surface is ground; the curable material is then removed; and then the wafer is mounted on the wafer holding means so that the above-mentioned ground second surface is in contact with the wafer holding means, and then the first surface is ground (e.g., refer to Patent Document 1.). In this manufacturing method of wafer, a thickness of the curable material applied to the first surface of the wafer during the coating step is equal to or more than 40 μm but is less than 300 μm.

In the manufacturing method of wafer constituted in this way, since the thickness of the curable material to be applied is equal to or more than 40 μm but is less than 300 μm when grinding the second surface of the wafer, surface waving on the wafer can sufficiently be absorbed and therefore the surface waving is not transferred on a processed surface of the wafer at the time of grinding. Thus, the second surface of the wafer is processed so as to be a uniform flat surface where the surface waving is removed by means of the grinding operation, without performing a lapping step or a double-head grinding step. Moreover, when grinding the first surface of the wafer after removing the curable material applied to the first surface, since the second surface which is in contact with the chuck table is a flat surface, a flat surface of which the thickness is uniform can be processed without the surface waving being transferred to the first surface.

On the other hand, there has been disclosed a manufacturing method of wafer, wherein: a curable resin composition, of which cure shrinkage is equal to or less than 7% and a value of a storage elastic modulus at 25° C. is within a range from 1.0×10⁶ to 3.0×10⁹ Pa at a film thickness of 10 μm to 200 μm, is applied to a first surface of a thin-plate wafer produced by slicing an ingot; a second surface of the wafer applied with a curable resin composition is pressed by a pressing means to planarize the curable resin composition layer applied to the first surface; after releasing the pressing by the pressing means, the curable resin composition layer applied to the wafer is irradiated with active energy beams so as to be cured on the wafer surface; and after applying flatly a grinding process to the second surface of the wafer fixed with the curable resin composition layer, the first surface is subjected to a grinding process with the second surface of the wafer planarized by means of a surface processing step as a reference surface (e.g., refer to Patent Document 2.).

In the manufacturing method of wafer configured to be in this way, the curable resin composition layer is formed by applying the curable resin composition to the first surface of the wafer produced by slicing the ingot; the wafer is processed to be a planarized surface by uniformly pressing the wafer by the pressing means having a planarized platy member etc., so that a surface on which the curable resin composition layer is formed becomes a bottom surface; and after the pressing means is removed from the wafer, the curable resin composition layer is cured by being irradiated with the active energy beam, and then the second surface on the reverse side of the planarized surface of the wafer is ground. In this case, the curable resin composition, of which the value of the storage elastic modulus at 25° C. is within a range from 1.0×10⁶ to 3.0×10⁹ Pa at a film thickness of 10 μm to 200 μm, is applied to the first surface of the wafer, and thereby surface waving on the wafer can sufficiently be absorbed by this curable resin composition layer and therefore the surface waving is not transferred on a processed surface of the wafer during the grinding processing step.

Then, after removing the curable resin composition layer applied to the first surface, the first surface of the wafer is ground. At this time, since the second surface being in contact with the fixing member is a planarized surface, the first surface can be processed so as to be a planarized surface of which the thickness is uniform, without the surface waving being transferred to the first surface. Thus, in the grinding step, the surface waving on the wafer caused at the time of slicing can be removed.

Patent Document 1: JP-A-2006-269761 (claim 1, paragraphs [0012] and [0013], and FIG. 1)

Patent Document 2: JP-A-2009-272557 (claim 1, paragraphs [0015] and [0016], FIG. 1)

### DISCLOSURE OF INVENTION

### Problem to be Solved by the Invention

However, in the manufacturing methods of wafer shown in above-mentioned conventional Patent Documents 1 and 2, there was problem that, since the curable resin composition layer formed on the surface of the wafer is merely a single layer, the curable resin composition shrinks at the time of being cured and thereby surface waving on the wafer is transferred to the curable resin composition layer. There was a problem that if the wafer surface is ground with reference to the surface of the curable resin composition layer to which the surface waving on the wafer is transferred, this surface waving on the curable resin composition layer is remained in the wafer after the grinding. Accordingly, there is a conceivable method of increasing the thickness of the curable resin composition layer in order that an influence due to the above-mentioned cure shrinkage of the curable resin composition should be reduced. However, since it will become easy to receive an influence of fluid (ease of flowing) before curing of the curable resin composition if the thickness of the curable resin composition layer is increased, there is a problem that it is difficult to planarize the surface of the curable resin composition layer, and therefore concavity and convexity are formed on the surface of the curable resin composition layer, in the manufacturing methods of wafer shown in above-mentioned conventional Patent Documents 1 and 2. There was a problem that if the wafer is ground with reference to the surface of the curable resin composition layer on which the concavity and convexity are formed, the concavity and convexity on the surface of the curable resin composition layer are transferred to the wafer after the grinding.

The object of the present invention is to provide a processing method of a semiconductor wafer, wherein a plurality of coating layers are formed on a semiconductor wafer surface having relatively large surface waving, and the surface waving on the outermost coating layer used as a reference at the time of grinding of the semiconductor wafer is reduced so that the surface is planarized, and thereby the surface waving on the semiconductor wafer after the grinding can be removed, and the surface thereof can be planarized. The other object of the present invention is to provide a processing method of a semiconductor wafer, wherein coating layers are formed a plurality of times on the semiconductor wafer surface so that a thickness of each coating layer is reduced, and thereby an influence of a cure shrinkage of curable material, e.g. a resin, used for forming the coating layer can be relaxed, and an influence of fluidity of the curable material, e.g. a resin, can also be relaxed, and therefore the surface of the outermost coating layer among the plurality of the coating layers can be formed in a stably planarized surface.

### Means for Solving Problem

Generally, for the purpose of removing surface waving on a semiconductor wafer (i.e., improvement of nanotopography), a planarized reference surface is formed by applying a curable material, e.g. elastic resin, to one surface (first surface) of the wafer so as to forma coating layer, and the wafer is supported without elastically deforming by adsorbing this reference surface, and then another surface (second surface) of the above-mentioned wafer is ground. However, with regard to a wafer having a large surface waving, the surface waving on the wafer cannot sufficiently be absorbed by merely one layer of the coating layer, and therefore the surface waving on the wafer is transferred to the coating layer surface, and the surface waving on the wafer cannot sufficiently be removed, i.e., the nanotopography cannot be improved. Accordingly, the inventor completed the present invention by gaining a knowledge that a coating layer is further formed on this coating layer surface where the surface waving is relaxed by means of one layer of the coating layer, and thereby the surface waving on the semiconductor wafer can be removed, i.e., the nanotopography can be improved.

A first aspect of the present invention is a processing method of the wafer characterized by including: a slicing step of slicing a semiconductor single crystal ingot by means of a wire saw device and obtaining a thin disc-like semiconductor wafer; a coating layer forming step of forming a planarized coating layer by applying a curable material to a whole first surface of this wafer; a coating layer curing step of curing this coating layer; a first surface grinding step of mounting the wafer on a table of a grinding apparatus so that a surface of this cured coating layer abuts on a reference surface of the table, and subsequently flatly grinding a second surface on a reverse side of the first surface of the wafer by means of the grinding apparatus; a coating layer removing step of removing the cured coating layer from the first surface of the wafer; and a second surface grinding step of mounting the wafer in the table of the grinding apparatus so that the second surface of the wafer from which this coating layer is removed abuts on the reference surface of the table, and subsequently flatly grinding the first surface of the wafer by means of the grinding apparatus, wherein a surface height of the first surface of the wafer after the slicing step but before the coating layer forming step is frequency-analyzed, and the coating layer forming step and the coating layer curing step are repeated a plurality of times if an amplitude of surface waving on the first surface of the wafer in a wavelength region of 10 mm to 100 mm is equal to or more than 0.5 μm.

A second aspect of the present invention corresponds to an invention on the basis of the first aspect, further characterized in that the surface height of the first surface of the wafer after the slicing step and but before the coating layer forming step is frequency-analyzed, the coating layer forming step and the coating layer curing step are repeated twice if the amplitude of the surface waving on the first surface of the wafer in the wavelength region of 10 mm to 100 mm is equal to or more than 0.5 μm but is less than 2.0 μm.

A third aspect of the present invention corresponds to an invention on the basis of the first aspect, further characterized in that the surface height of the first surface of the wafer after the slicing step and but before the coating layer forming step is frequency-analyzed, the coating layer forming step and the coating layer curing step are repeated 3 times if the amplitude of the surface waving on the first surface of the wafer in the wavelength region of 10 mm to 100 mm is equal to or more than 2.0 μm.

### Effect of the Invention

In the processing method of the semiconductor wafer in the first aspect of the present invention, a surface height of the first surface of the wafer after the slicing step but before the coating layer forming step is frequency-analyzed, and the coating layer forming step and the coating layer curing step are repeated a plurality of times if the amplitude of surface waving on the first surface of the wafer in the wavelength region of 10 mm to 100 mm is equal to or more than 0.5 μm. Accordingly, the surface waving on the outermost coating layer used as a reference at the time of grinding of the wafer among a plurality of the coating layers formed on the first surface of the wafer of which the amplitude of the surface waving is relatively large is reduced, and thereby the surface thereof is planarized. Consequently, since the wafer is ground by using the planarized surface of the outermost coating layer as a reference surface, the surface waving on the wafer can be removed and the surface thereof can be planarized. Moreover, the coating layers are formed a plurality of times on the semiconductor wafer surface so that a thickness of each coating layer is reduced, and thereby an influence of a cure shrinkage of curable material, e.g. a resin, used for forming the coating layer can be relaxed, and an influence of fluidity of the curable material, e.g. a resin, can also be relaxed. Consequently, the surface of the outermost coating layer among the plurality of the coating layers can be formed in a stably planarized surface. In addition, if the amplitude of the surface waving on a first surface of the wafer in the wavelength region of 10 mm to 100 mm is less than 0.5 μm, the surface waving on the coating layer is reduced even by performing the coating layer forming step and the coating layer curing step only once, and thereby the surface is planarized.

In the processing method of the semiconductor wafer in the second aspect of the present invention, a surface height of the first surface of the wafer after the slicing step but before the coating layer forming step is frequency-analyzed, and the coating layer forming step and the coating layer curing step are repeated twice if the amplitude of the surface waving on the first surface of the wafer in the wavelength region of 10 mm to 100 mm is equal to or more than 0.5 μm but is less than 2.0 μm. Consequently, a first coating layer and a second coating layer are formed on the first surface of the wafer in this order. Accordingly, by a relatively few repetition of the coating layer forming steps and the coating layer curing steps, the surface waving on the second coating layer used as the reference at the time of the grinding of the wafer is reduced, and thereby the surface can be planarized. Consequently, the surface waving on the wafer after the grinding can be certainly removed, and thereby the surface thereof can be certainly planarized.

In the processing method of the semiconductor wafer in the third aspect of the present invention, a surface height of the first surface of the wafer after the slicing step but before the coating layer forming step is frequency-analyzed, and the coating layer forming step and the coating layer curing step are repeated 3 times if the amplitude of the surface waving on the first surface of the wafer in the wavelength region of 10 mm to 100 mm is equal to or more than 2.0 μm. Consequently, the first coating layer, the second coating layer, and a third coating layer are formed on the first surface of the wafer in this order. Accordingly, even if the amplitude of the surface waving on the first surface of the wafer is relatively large, the surface waving on the third coating layer used as the reference at the time of grinding of the wafer can be reduced, and thereby the surface thereof can be planarized. Consequently, the surface waving on the wafer after the grinding can be certainly removed, and thereby the surface thereof can be certainly planarized.

### BRIEF DESCRIPTION OF DRAWINGS

FIG. 1 is a flow chart showing schematic steps of a processing method of a semiconductor wafer of embodiments of the present invention.

FIG. 2 is a schematic cross section showing a difference between an amplitude of surface waving on a first coating layer surface when the first coating layer is formed on a wafer in a first coating layer forming step and an amplitude of surface waving on the second coating layer surface when the second coating layer is formed on the wafer in a second coating layer forming step, among the schematic steps.

FIG. 3 is a scheme process chart showing a range from the first coating layer forming step to a second surface grinding step, among the schematic steps.

FIG. 4 is a schematic cross section showing a state of a wafer in each step in wafer processing of an Example 1.

FIG. 5 is a schematic cross section showing a state of a wafer in each step in wafer processing of a Comparative Example 1.

FIG. 6 is a schematic cross section showing a state of a wafer in each step in wafer processing of a Comparative Example 2.

FIG. 7 is a schematic cross section showing a state of a wafer in each step in wafer processing of a Comparative Example 3.

FIG. 8 is a chart showing nanotopography (surface waving) of each wafer after the processing of each of the Example 3, the Example 4, and the Comparative Examples 4 to 6 is subjected to a material (wafer) of which an amplitude of surface waving is equal to or more than 0.5 μm but is less than 2.0 μm.

FIG. 9 is a chart showing nanotopography (surface waving) of each wafer after the processing of each of the Example 1, the Example 2, and the Comparative Examples 1 to 3 is subjected to a material (wafer) of which an amplitude of surface waving is equal to or more than 2.0 μm.

FIG. 10 is a nanotopography map (chart showing a height distribution (difference in height) of the wafer surface) after mirror polishing is further subjected to each wafer subjected to the processing of each of the Example 1, the Example 2, and Comparative Examples 1 to 3.

FIG. 11 is a chart showing a frequency analysis result of surface waving on each wafer after the processing of each of the Example 1, the Example 2, and the Comparative Example 1 is subjected to the material (wafer) of which an amplitude of surface waving is equal to or more than 0.5 μm but is less than 2.0 μm.

FIG. 12 is a chart showing a frequency analysis result of surface waving on each wafer after the processing of each of the Example 3, the Example 4, and the Comparative Example 4 is subjected to the material (wafer) of which an amplitude of surface waving is equal to or more than 2.0 μm.

FIG. 13 is a chart showing a frequency analysis result of surface waving on each wafer after the processing of each of the Example 1, the Example 2, and the Comparative Example 1 is subjected to the material (wafer) of which an amplitude of surface waving is equal to or more than 0.5 μm but is less than 2.0 μm, and then the mirror polishing is further subjected thereto.

FIG. 14 is a chart showing a frequency analysis result of surface waving on each wafer after the processing of each of the Example 3, the Example 4, and the Comparative Example 4 is subjected to the material (wafer) of which an amplitude of surface waving is equal to or more than 2.0 μm, and then the mirror polishing is further subjected thereto.

FIG. 15 is a chart showing a frequency analysis result of surface waving on each wafer after the processing of each of Reference Examples 1 to 3 is subjected to a material (wafer) of which an amplitude of surface waving is less than 0.5 μm.

FIG. 16 is a chart showing a frequency analysis result of surface waving on each wafer after the processing of each of the Reference Examples 1 to 3 is subjected to the material (wafer) of which an amplitude of surface waving is less than 0.5 μm.

### MODE FOR CARRYING OUT THE INVENTION

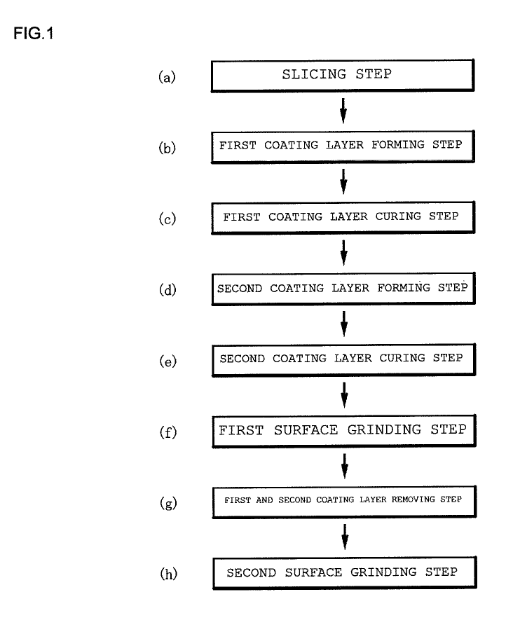

Next, embodiments of the present invention will now be explained with reference to the drawings. As shown in FIGS. 1(a) to 1(h), a processing method of a semiconductor wafer of a present invention includes: a slicing step of slicing a semiconductor single crystal ingot by means of a wire saw device and obtaining a thin disc-like wafer (FIG. 1 (a)); a coating layer forming step of forming a planarized coating layer by applying a curable material to a whole first surface of this wafer (FIGS. 1 (b) and 1(d)); a coating layer curing step of curing this coating layer (FIGS. 1(c) and 1(e)); a first surface grinding step of mounting the wafer on a table of a grinding apparatus so that a surface of this cured coating layer abuts on a reference surface of the table, and subsequently flatly grinding a second surface on a reverse side of the first surface of the wafer by means of the grinding apparatus (FIG. 1(f)); a coating layer removing step of removing this cured coating layer from the first surface of the wafer (FIG. 1(g)); and a second surface grinding step of mounting the wafer in the table of the grinding apparatus so that the second surface of the wafer from which the coating layer is removed abuts on the reference surface of the table, and subsequently flatly grinding the first surface of the wafer by means of the grinding apparatus (FIG. 1(h)). As the semiconductor wafer, silicon wafers, silicon carbide (SiC) wafers, gallium arsenide (GaAs) wafers, sapphire wafers, etc. are listed, and as the semiconductor single crystal ingot, silicon single crystal ingots, silicon carbide (SiC) single crystal ingots, gallium arsenide (GaAs) single crystal ingots, sapphire single crystal ingots, etc. are listed. Although a chamfering step of chamfering an outer peripheral portion of the semiconductor wafer is not in particular shown in FIG. 1, the chamfering step may be performed after any one step among the respective steps of FIG. 1(a) to FIG. 1(h), e.g.: primary chamfering is performed after the step of FIG. 1 (a); and secondary chamfering with a chamfering amount larger than that of the primary chamfering is performed after the step of FIG. 1(h). The chamfering step may be performed a plurality of times.

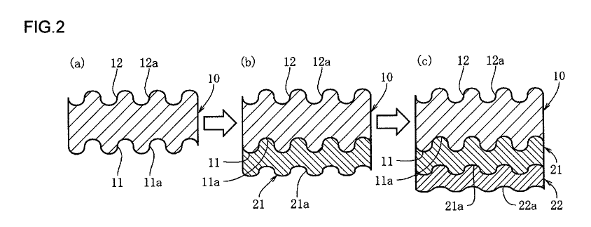

As shown in FIG. 2(a), concavo-convex surface waving 11a as periodically undulated is generated, on a first surface 11 of a wafer 10 immediately after slicing, and concavo-convex surface waving 12a as periodically undulated is generated on a second surface 12 of the wafer 10 immediately after slicing. The characteristic configuration of the present invention is that: a surface height of the first surface of the wafer 10 after the slicing step but before the coating layer forming step is frequency-analyzed; and the coating layer forming step and the coating layer curing step are repeated a plurality of times if an amplitude of the surface waving 11a on the first surface of the wafer in a wavelength region of 10 mm to 100 mm is equal to or more than 0.5 μm. Moreover, it is preferable that the coating layer forming step and the coating layer curing step are repeated twice if the amplitude of the surface waving 11a on the first surface of the wafer 10 in the wavelength region of 10 mm to 100 mm is equal to or more than 0.5 μm but is less than 2.0 μm. Moreover, it is preferable that the coating layer forming step and the coating layer curing step are repeated 3 times if the amplitude of the surface waving on the first surface of the wafer in the wavelength region of 10 mm to 100 mm is equal to or more than 2.0 μm. In addition, a double-sided simultaneous planarizing process, e.g. double-sided lapping processing and double-head grinding processing, without a reference surface may be performed after the slicing step but before the first coating layer forming step. Thus, before forming the starting coating layer (first coating layer 21) on a first surface 11 of the wafer 10, the surface waving 11a on the first surface 11 and the surface waving 12a on the second surface 12 of the wafer 10 in the specified wavelength region (10 mm to 100 mm) can be relaxed in advance.

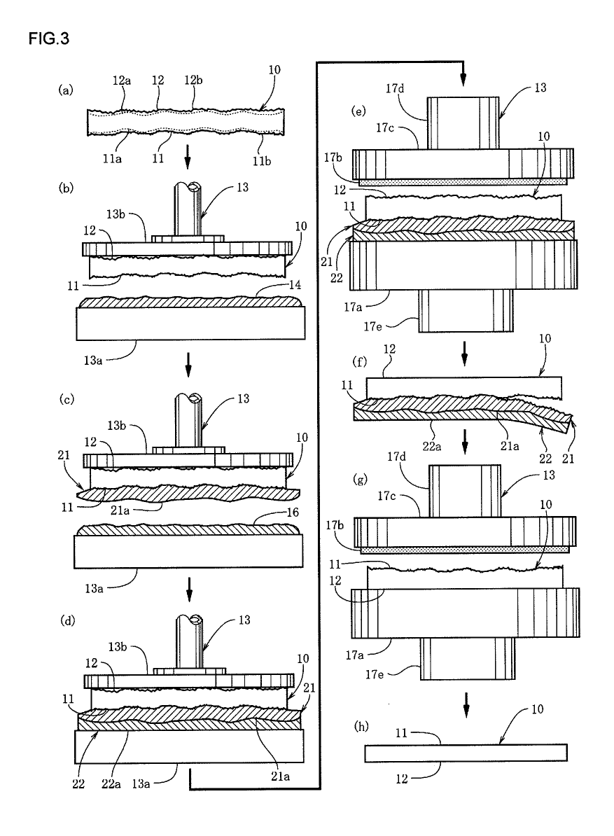

FIGS. 1 to 3 show a case where the amplitude of the surface waving 11a on the first surface 11 of the wafer 10 in the wavelength region of 10 mm to 100 mm is equal to or more than 0.5 μm but less than 2.0 μm. In this case, it is preferable to repeat the coating layer forming step and the coating layer curing step twice. Here, it is preferable that the coating layer forming step and the coating layer curing step are repeated twice if the amplitude of the surface waving 11a on the first surface 11 of the wafer 10 in the wavelength region of 10 mm to 100 mm is equal to or more than 0.5 μm but is less than 2.0 μm. This is because the surface waving 22a on the second coating layer 22 can be extremely reduced even by repeating the coating layer forming step and the coating layer curing step only twice since the amplitude of the surface waving 11a on the first surface 11 of the wafer 10 is relatively as small as equal to or more than 0.5 μm but less than 2.0 μm (FIG. 2). More specifically, since the cured first coating layer 21 is firstly formed on the first surface 11 of the wafer 10 through the first coating layer forming step and the first coating layer curing step, and thereby the surface waving 11a on the first surface 11 of the wafer 10 is relaxed and then is transferred to the surface of the first coating layer 21, the surface waving 21a on the first coating layer 21 becomes smaller than the surface waving 11a on the first surface 11 of the wafer 10 (FIGS. 2 (b) and 3(c)). Next, since the cured second coating layer 22 is formed thereon through the second coating layer forming step and the second coating layer curing step, and thereby the surface waving 21a on the first surface 21 is relaxed and then is transferred to the surface of the second coating layer 22, the surface waving 22a on the second coating layer 22 becomes extremely small (FIG. 2(c)).

On the other hand, when the amplitude of the surface waving on the first surface of the wafer in the wavelength region of 10 mm to 100 mm is equal to or more than 2.0 μm, it is preferable to repeat the coating layer forming step and the coating layer curing step 3 times and form a first coating layer cured on this first surface of the wafer, to forma second coating layer cured on the surface of this first coating layer, and to further forma third coating layer cured on the surface of this second coating layer. The preferable number of repetitions of the coating layer forming step and the coating layer curing step is 3. This is because surface waving on the third coating layer can be made extremely small by forming the third coating layer on the surface of this second coating layer, although the surface waving on the second coating layer can be reduced to a certain degree, but cannot be extremely reduced, even if the coating layer forming step and the coating layer curing step are repeated twice since the amplitude of the surface waving on the first surface of the wafer is relatively large, e.g., equal to or more than 2.0 μm. In addition, if the amplitude of the surface waving on the first surface of the wafer in the wavelength region of 10 mm to 100 mm is less than 0.5 μm, the surface waving on the coating layer can be reduced even by performing the coating layer forming step and the coating layer curing step only once, and thereby the surface can be planarized.

On the other hand, since the surface waving 21a on the first coating layer 21 becomes smaller than the surface waving 11a on the wafer 10 if the coating layer forming step and the coating layer curing step are repeated twice, it is preferable to form a thickness of the second coating layer 22 thinner than a thickness of the first coating layer 21 (FIGS. 2 and 3). For Example, it is preferable to form the thickness of the first coating layer 21 within a range from 40 μm to 200 μm, and to form the thickness of the second coating layer 22 within a range from 20 μm to 100 μm so as to be thinner than the thickness of the first coating layer 21. More specifically, it is preferable to form the thickness of the second coating layer 22 within a range from 0.4 to 0.7, in terms of the thickness of the first coating layer 21 of 1. In this case, total resin cost can be reduced by making the thickness of the second coating layer 22 thinner than the thickness of the first coating layer 21. Moreover, in the same manner as the case where the coating layer forming step and the coating layer curing step are repeated twice, it is preferable to form the thickness of the second coating layer thinner than the thickness of the first coating layer, and to form a thickness of the third coating layer thinner than the thickness of the second coating layer, even when the coating layer forming step and the coating layer curing step are repeated 3 times. For Example, it is preferable to form the thickness of the first coating layer within a range from 40 μm to 200 μm, to form the thickness of the second coating layer within a range from 20 μm to 140 μm so as to be thinner than the thickness of the first coating layer, and to form the thickness of the third coating layer within a range from 10 μm to 80 μm so as to be thinner than the thickness of the second coating layer. More specifically, it is preferable to form the thickness of the second coating layer within a range from 0.4 to 0.7 and to form the thickness of the third coating layer within the range from 0.2 to 0.4, in terms of the thickness of the first coating layer of 1. In this case, total resin cost can be reduced by making the thicknesses gradually thinner, in the order from the first coating layer to the third coating layer.

The specific processing method of the semiconductor wafer 10 of the present invention will now be explained in detail with reference to FIG. 3. FIG. 3(a) shows a state of a wafer 10 immediately after slicing, which is cut by a fixed abrasive grain wire saw. A known multi-wire saw device (not shown) is used for this slice, and a plurality of the wafer 10 can be manufactured from an ingot at once. The multi-wire saw device includes a plurality of guide rollers provided with a plurality of grooves for guiding wires, and a plurality of ultrathin steel wires are wound between the guide roller and the guide roller. The multi-wire saw device is a device for cutting an object to be cut into a plurality of sheets by pressing the object to be cut on a plural rows of wires exposed between the guide roller and the guide roller, by rotating rollers at high speed. As the multi-wire saw device, there are a fixed abrasive grain method and a free abrasive grain method, depending on how to use the abrasive grain for cutting. In the fixed abrasive grain method, steel wires to which diamond abrasive grains etc. are adhered by means of vacuum evaporation etc. are used for the wires. The free abrasive grain method is used while applying slurry mixed with abrasive grains and oil agent to the wire. In the fixed abrasive grain method, since the wire itself to which the abrasive grains are fixed is used for cutting an object to be cut, cutting time is relatively short and productivity thereof is excellent. Moreover, since the fixed abrasive grain method does not use slurry, there is no need to discard slurry with which scraps after cutting are mixed, and therefore is gently economical also with respect to environment. Although both methods may be used for the present invention, it is preferable to use the fixed abrasive grain method which is advantageous in the light of environment and economy. In addition, if the fixed abrasive grain multi-wire saw is used, there is a problem that the nanotopography (surface waving) becomes worse since a processing damage given to the wafer 10 surface is serious and the surface waving 11a and 12a generated on the wafer 10 after the cutting also becomes relatively large. However, the wafer 10 excellent in the nanotopography characteristics (i.e., the value of the nanotopography is small) can be manufactured by using the processing method of the present invention.

Concavo-convex surface waving 11a periodically undulated and processing strain (processing damage layer) 11b due to the wire saw cutting are generated on the first surface 11 of the wafer 10 which is cut immediately after the slicing by means of the fixed abrasive grain multi wire saw. Moreover, concavo-convex surface waving 12a which is periodically undulated and processing strain (processing damage layer) 12b due to the wire saw cutting are generated on the second surface 12 of the wafer 10 immediately after the slicing (FIG. 3 (a)). Accordingly, although not shown in FIG. 3, a double-sided simultaneous planarizing process, e.g. a double-sided lapping processing or a double-head grinding processing, not having a reference surface may be performed with respect to the wafer 10. Thus, before forming the first coating layer 21 on the first surface 11 of the wafer 10, the surface waving 11a of the first surface 11 and the surface waving 12a of the second surface 12 of the wafer 10 in the specified wavelength region (10 mm to 100 mm) can be relaxed in advance.

FIGS. 3 (b) to 3 (d) show an Example of holding/pressing device 13 used for the first coating layer forming step and the second coating layer forming step. Firstly, a curable material 14 used for the first coating layer 21 is dropped to be applied to a plate 13a planarized with a high precision by means of holding and a pressing device 13 (FIG. 3 (b)). Subsequently, a pressing table 13b of the holding/pressing device 13 is made to suction-hold the second surface 12 of the wafer 10, and then the pressing table 13b is moved to the lower side so that the first surface 11 of the wafer 10 is pressed to the curable material 14. Next, the pressure of the pressing table 13b is released, the curable material 14 is cured on the first surface 11 of the wafer 10 so as to form the first coating layer 21, in a state where no elastic deformation is applied to the surface waving 11a which remains on the first surface 11 of the wafer 10. Since the surface waving 11a on the first surface 11 of the wafer 10 is relaxed and then is transferred to the surface of the first coating layer 21 when this curable material 14 is cured, the surface waving 21a on the first coating layer 21 is smaller than the surface waving 11a on the first surface 11 of the wafer 10 (FIG. 2(b)).

Next, after moving the pressing table 13b up with the wafer 10 and the first coating layer 21 and then removing the first coating layer 21 from the plate 13a, a curable material 16 used for the second coating layer 22 is dropped to be applied to the plate 13a (FIG. 3(c)). Moreover, the pressing table 13b is moved to the lower side so that the surface of the first coating layer 21 on the first surface 11 of the wafer 10 is pressed to the curable material 16 (FIG. 3(d)). Next, the pressure of the pressing table 13b is released, the curable material 16 is cured on the first coating layer 21 on the first surface 11 of the wafer 10 so as to form the second coating layer 22, in a state where no elastic deformation is applied to the surface waving 21a which remains on the first coating surface 21. Since the surface waving 21a on the first coating layer 21 is relaxed and then is transferred to the surface of the second coating layer 22 when this curable material 16 is cured, i.e., since the surface waving 11a on the first surface 11 of the wafer 10 is further relaxed and then is transferred to the surface of the second coating layer 22, the surface waving 22a on the second coating layer 22 becomes extremely small (FIG. 2(c)). This surface of the second coating layer 22 having the extremely small surface waving 22a is used as the reference surface at the time of the grinding of the second surface 12 of the wafer 10. In addition, the first coating layer 21 is bonded on the first surface 11 of the wafer 10, and the second coating layer 22 is bonded on the surface of the first coating layer 21. That is, the first and second coating layers 21 and 22 is laminated and bonded on the first surface 11 of the wafer 10.

As a method of coating the curable material 14 on the first surface 11 of the wafer 10, the following methods are listed: a spin coat method of dropping the curable material 14 on this first surface 11 with the first surface 11 of the wafer 10 facing upward, and rotating the wafer 10 so as to spread the curable material 14 on the whole of the first surface 11; a screen printing method of pressing the curable material 14, by means of a squeegee, placed on the screen film disposed on the first surface 11 of the wafer 10; and a method of pressing an applied surface so as to be contacted with a surface on the flat plate planarized with a high precision after coating by spraying on the whole first surface 11 of the wafer 10 by means of an electric spray deposition method etc. There are not only these methods but also a method of planarizing the first surface 11 of the wafer 10 by the curable material 14 with a high precision. Also when applying the curable material 16 to the first coating layer 21 surface, it is applied by the similar method to the above-mentioned methods. As the curable materials 14 and 16, a thermosetting resin, a heat-reversible resin, a photosensitive resin, etc. are listed, and these curable materials 14 and 16 are preferable in terms of the ease of being removed after the processing. In particular the photosensitive resin is preferred also in that no stress due to heat is applied. In Examples mentioned below, UV curing resins are used as the curable materials 14 and 16. Moreover, synthetic rubber, adhesive agents (wax etc.), etc. are listed as materials of other specific curable materials 14 and 16.

FIG. 3 (e) shows an Example of a surface grinding device 17 used for the first surface grinding step. Firstly, the surface of the second coating layer 22 formed on the first surface 11 of the wafer 10 via the first coating layer 21 is placed and then is suction-held on an upper surface planarized with a high precision of a vacuum chuck table 17a of the surface grinding device 17. Subsequently, a surface plate 17c in which a grindstone 17b fixed to a lower surface is disposed above this wafer 10. Next, the surface plate 17c is dropped with the grindstone 18b so that a lower surface of the grindstone 17b is contacted with the second surface 12 of the wafer 10, a spindle 17d at an upper side of the surface plate 17c and a spindle 17e at a lower side of the vacuum chuck table 17a are rotated in directions opposite to each other, and then the second surface 12 of the wafer 10 is ground by rotating and contacting the lower surface of the grindstone 17b and the second surface 11 of the wafer 10 with each other.

FIG. 3(f) shows first and second coating layer removing steps. The first and second coating layers 21 and 22, in which the second surface 12 of the wafer 10 is laminated and bonded by means of the first surface grinding step on the first surface 11 of the wafer 10 planarized with a high precision, are removed from the wafer 10. Note that the first and second coating layers may be chemically removed using a solvent.

FIG. 3(g) shows an Example of a second surface grinding step. The surface grinding device 17 is identical to the surface grinding device used for the first surface grinding step. Firstly, the second surface 12 of the wafer 10 planarized with a high precision is placed to be suction-held on the first surface grinding step on the upper surface planarized with a high precision of the vacuum chuck table 17a. Subsequently, a surface plate 17c in which a grindstone 17b fixed to a lower surface is disposed above this wafer 10. Next, the surface plate 17c is dropped with the grindstone 17b so that a lower surface of the grindstone 17b is contacted with the first surface 11 of the wafer 10, a spindle 17d at an upper side of the surface plate 17c and a spindle 17e at a lower side of the vacuum chuck table 17a are rotated in directions opposite to each other, and then the first surface 11 of the wafer 10 is ground by rotating and contacting the lower surface of the grindstone 17b and the first surface 11 of the wafer 10 with each other. Consequently, the surface waving 12a and the processing strain (processing damage layer) 12b of the second surface 12 are removed in the first surface grinding step, the surface waving 11a and the processing strain (processing damage layer) 11b of the first surface 11 are removed in the second surface grinding step, and then the wafer 10 of which the first surface 11 and the second surface 12 are planarized is obtained (FIG. 3(h)). Moreover, since the first and second coating layers 21 and 22 are formed by repeating the coating layer forming step and the coating layer curing step twice on the first surface 11 of the wafer 10, and thereby the respective thicknesses of the first and second coating layers 21 and 22 can be reduced, an influence of the cure shrinkage of the curable materials 14 and 16, e.g. a resin, used for forming the first and second coating layers 21 and 22 can be relaxed, and an influence of fluidity of the curable materials 14 and 16, e.g. a resin, can also be relaxed.

Next, Examples of the present invention will now be explained in detail with Comparative Examples and Reference Examples.

### Example 1

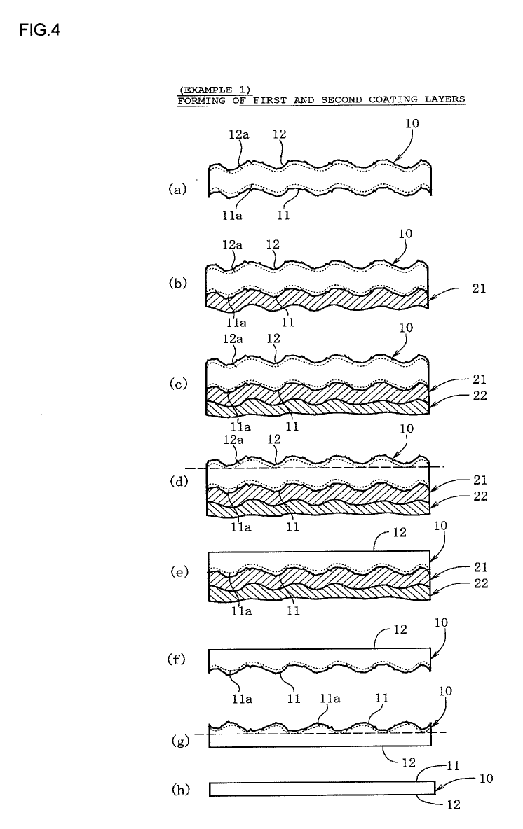

Firstly, silicon single crystal ingot is cut (sliced) by means of the fixed abrasive grain multi-wire saw device, and thereby a plurality of the silicon wafers 300 mm in diameter is manufactured. Then, a surface height of the first surface 11 of the wafer 10 is frequency-analyzed, and the wafer 10 of which the amplitude of surface waving 11a on the first surface 11 of the wafer 10 (amplitude of the surface waving of the material) in the wavelength region of 10 mm to 100 mm is equal to or more than 0.5 μm but is less than 2.0 μm is selected (FIG. 4(a)). After coating a UV curing resin as a curable material onto the first surface 11 of this selected wafer 10 in the first coating layer forming step (FIG. 4(b)), this curable material composed of the UV curing resin is cured in the first coating layer curing step, and thereby the first coating layer 21 is formed on the first surface 11 of the wafer 10. Subsequently, after applying the UV curing resin as a curable material to the surface of the first coating layer 21 formed on the first surface 11 of the wafer 10 in the second coating layer forming step (FIG. 4(c)), this curable material composed of the UV curing resin is cured in the second coating layer curing step, and thereby the second coating layer 22 is formed on the surface of the first coating layer 21. That is, the coating layer forming step and the coating layer curing step are repeated twice. Next, the wafer 10 is held by attracting the surface of the second coating layer 21 formed on the first surface 11 of the wafer 10 via the first coating layer 21 onto the flat plate 13a (FIG. 3) of the holding/pressing device 13, and the first and second coating layers 21 and 22 are removed therefrom (FIG. 4(f)) after the second surface 12 of this wafer 10 is flatly ground to the dashed line of FIG. 4 (d) (FIG. 4(e)). Furthermore, the wafer 10 is held by attracting the second surface 12 of the wafer 10 which is flatly ground on the flat plate (FIG. 3) of the holding/pressing device, and then the first surface 11 of this wafer 10 is flatly ground to the dashed line of FIG. 4(g) (FIG. 4(h)). This wafer 10 is referred to as the Example 1.

### Example 2

A wafer of which both surfaces are ground is obtained in a similar manner to the Example 1, except that the coating layer forming step and the coating layer curing step are repeated 3 times. This wafer is referred to as the Example 2.

### Example 3

A wafer of which both surfaces are ground is obtained in a similar manner to the Example 1, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is equal to or more than 2.0 μm is selected. This wafer is referred to as the Example 3.

### Example 4

A wafer of which both surfaces are ground is obtained in a similar manner to the Example 1, except that: the coating layer forming step and the coating layer curing step are repeated 3 times; and a surface height of the first surface of the wafer is frequency-analyzed; and the wafer of which the amplitude of surface waving on the first surface of the wafer (amplitude of the surface waving of the material) in the wavelength region of 10 mm to 100 mm is equal to or more than 2.0 μm is selected. This wafer is referred to as the Example 4.

### Comparative Example 1

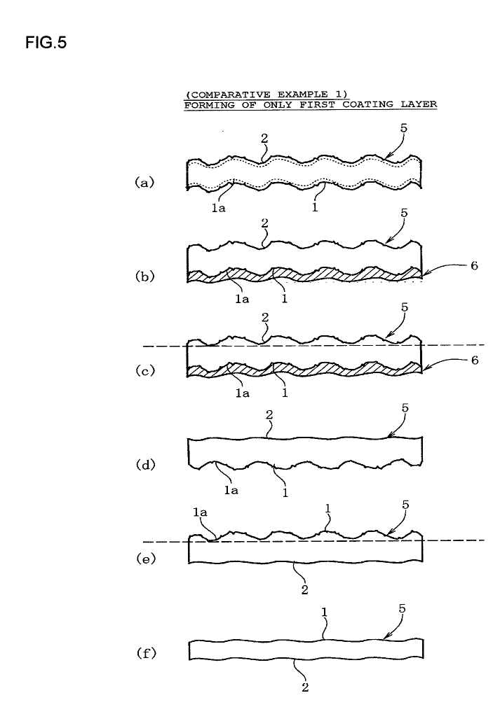

As shown in FIG. 5, a surface height of a first surface 1 of a wafer 5 is frequency-analyzed; and the wafer 5 of which the amplitude of surface waving 1a on the first surface 1 of the wafer (amplitude of the surface waving of the material) in the wavelength region of 10 mm to 100 mm is equal to or more than 0.5 μm but is less than 2.0 μm is selected. Then, after a first coating layer 6 is formed on the first surface 1 of the wafer 5 by performing the coating layer forming step and the coating layer curing step once with respect to the first surface 1 of this wafer 5 (FIGS. 5 (b) and 5 (c)), a second surface 2 of the wafer 5 is ground to the dashed line of FIG. 5 (c) with reference to the surface of the first coating layer 6 (FIG. 5 (d)), and the first surface 1 of the wafer 5 is ground to the dashed line of FIG. 5 (e) with reference to the second surface 2 (FIG. 5 (f)). This wafer 5 is referred to as the Comparative Example 1.

### Comparative Example 2

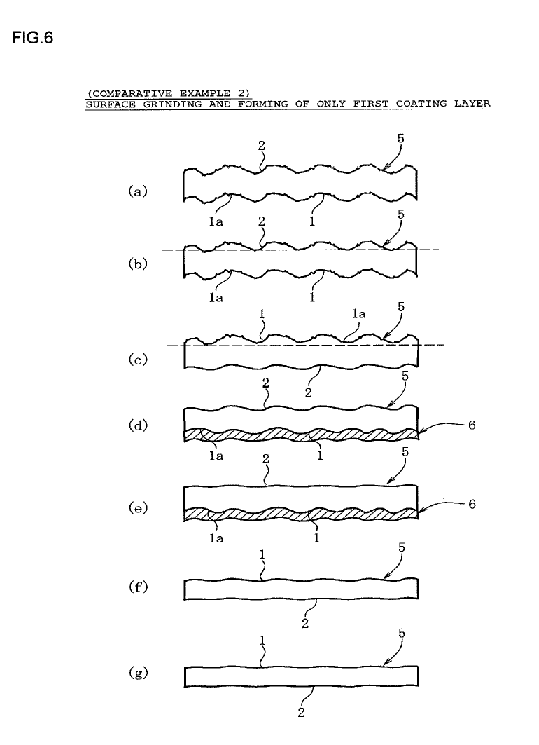

As shown in FIG. 6, firstly, a surface height of the first surface 1 of the wafer 5 is frequency-analyzed; and the wafer 5 of which the amplitude of surface waving 1a on the first surface 1 of the wafer (amplitude of the surface waving of the material) in the wavelength region of 10 mm to 100 mm is equal to or more than 0.5 μm but is less than 2.0 μm is selected. Subsequently, after grinding the second surface 2 of the wafer 5 to the dashed line of FIG. 6 (b) with reference to the first surface 1 of the wafer 5, the first surface 1 of the wafer 5 is ground to the dashed line of FIG. 6 (c) with reference to the second surface 2 of the wafer 5. Next, the first coating layer 6 composed of the curable material composed of a UV curing resin is formed on the first surface 1 of the wafer 5 by performing the coating layer forming step and the coating layer curing step once (FIG. 6(d)). Moreover, after grinding the second surface 2 of the wafer 5 with reference to the surface of the first coating layer 6 (FIG. 6(e)), the first coating layer 6 is removed from the wafer 6 (FIG. 6(f)), and the first surface 1 of the wafer 5 is ground with reference to the second surface 2 of the wafer 5 (FIG. 6(g)). This wafer 5 is referred to as the Comparative Example 2.

### Comparative Example 3

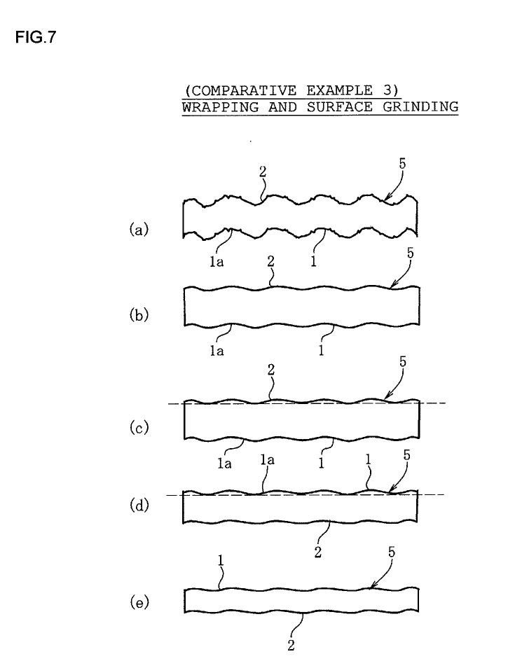

As shown in FIG. 7, firstly, after a surface height of the first surface 1 of the wafer 5 is frequency-analyzed; and the wafer 5 of which the amplitude of surface waving 1a on the first surface 1 of the wafer (amplitude of the surface waving of the material) in the wavelength region of 10 mm to 100 mm is equal to or more than 0.5 μm but is less than 2.0 μm is selected, the first surface 1 and the second surface 2 of the wafer 5 are wrapped (FIG. 7(b)). Next, the second surface 2 of the wafer 5 is ground to the dashed line of FIG. 7(c) with reference to the first surface 1 of the wafer 5 (FIG. 7(d)). Furthermore, the first surface 1 of the wafer 5 is ground to the dashed line of FIG. 7(d) with reference to the second surface 2 of the wafer 5 (FIG. 7(e)). This wafer 5 is referred to as the Comparative Example 3. The above-mentioned wrapping is a step of performing simultaneously a planarizing process of the first surface 1 and the second surface 2 of the wafer 5 by means of a lapping device (not shown).

### Comparative Example 4

The first coating layer is formed on the first surface of the wafer and then the second surface and the first surface of the wafer are ground, in a similar manner to the Comparative Example 1, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is equal to or more than 2.0 μm is selected. This wafer is referred to as the Comparative Example 4.

### Comparative Example 5

The second surface and the first surface of the wafer are ground, then the first coating layer is formed on the first surface of this wafer, and then the second surface and the first surface of the wafer are further ground, in a similar manner to the Comparative Example 2, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is equal to or more than 2.0 μm is selected. This wafer is referred to as the Comparative Example 5.

### Comparative Example 6

Both surfaces of the wafer are wrapped and then the second surface and the first surface of this wafer are ground, in a similar manner to the Comparative Example 3, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is equal to or more than 2.0 μm is selected. This wafer is referred to as the Comparative Example 6.

### <Comparative Test 1 and Evaluation>

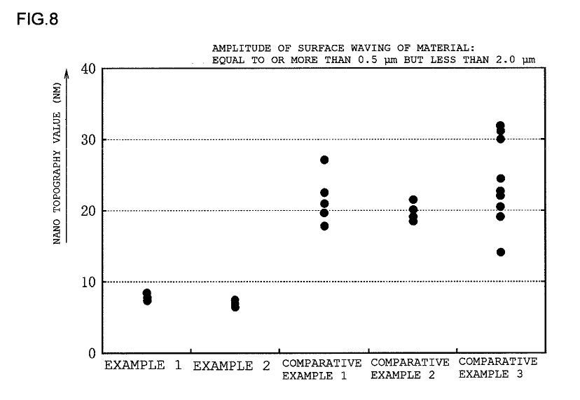

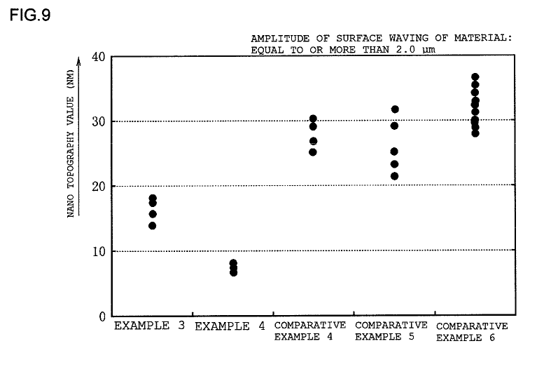

There is examined an influence of a surface shape of each wafer of the Examples 1 to 4 and Comparative Examples 1 to 6 to be exerted on the nanotopography (surface waving) of the wafer surface after performing the mirror polishing process. In this test, a plurality of wafers having the same conditions are respectively made for the Examples 1 to 4 and Comparative Examples 1 to 6. Then, after a rough grinding process of same condition is subjected to both surfaces of each wafer using a double-sided polishing apparatus as a common mirror polishing process, with respect to each of the plurality of the wafers, a final polishing process of same condition is subjected to the first surface of each wafer using an single-sided polishing apparatus, and thereby wafers in which the first surface of each wafer is mirror-polished are made. Then, a nanotopography value of the first surface of each wafer (difference in height of the surface waving) having a window size of 10 mm×10 mm is measured with respect to the first surface of each wafer which is mirror-polished using an optical-interference type flatness measuring device (Wafersight2 made by KLATencor). The results are shown in FIGS. 8 and 9.

As proved from FIGS. 8 and 9, the nanotopography value is increased to 17 to 27 nm, 18 to 22, nm and 14 to 32 nm in the Comparative Examples 1 to 3, and the nanotopography value is further increased to 25 to 31 nm, 22 to 32 nm, and 28 to 37 nm in the Comparative Examples 4 to 6. On the other hand, the nanotopography value is extremely decreased to 7 to 8 nm, 6 to 8 nm, and 6 to 8 nm in the Examples 1, 2, and 4, and the nanotopography value is relatively slightly decreased to 14 to 18 nm in the Example 3. Consequently, it is proved that: the nanotopography value is extremely decreased by repeating the coating layer forming step and the coating layer curing step only twice with respect to the wafer of which the amplitude on the surface waving of the material is equal to or more than 0.5 μm but is and less than 2.0 μm; the nanotopography value is relatively slightly decreased even by repeating the coating layer forming step and the coating layer curing step only twice with respect to the wafer of which the amplitude on the surface waving of the material is equal to or more than 2.0 μm; and the nanotopography value is extremely decreased by repeating the coating layer forming step and the coating layer curing step 3 times.

### <Comparative Test 2 and Evaluation>

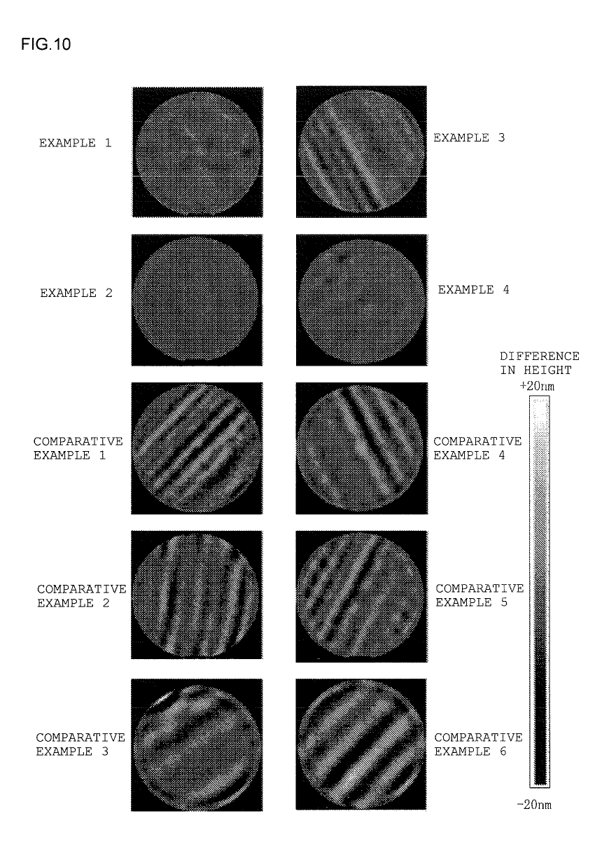

In this comparative test 2, there is examined an influence of a surface shape of each wafer of the Examples 1 to 4 and Comparative Examples 1 to 6 to be exerted on the nanotopography (surface waving) of the wafer surface after subsequently performing the mirror polishing process, in a similar manner to the comparative test 1. More specifically, firstly, after a rough grinding process of same condition is subjected to both surfaces of each wafer using a double-sided polishing apparatus as a common mirror polishing process, with respect to each of the plurality of the wafers respectively obtained in the Examples 1 to 4 and Comparative Examples 1 to 6, a final polishing process of same condition is subjected to the first surface of each wafer using an single-sided polishing apparatus, and thereby wafers in which the first surface of each wafer is mirror-polished are made. Then, a height distribution (difference in height) of each wafer surface is measured and a nanotopography map is made, with respect to the first surface of each wafer which is mirror-polished using an optical-interference type flatness measuring device (Wafersight2 made by KLA Tencor). This result thereof is shown in FIG. 10. FIG. 10 shows the measured result of the nanotopography in light and shade colors after the measured result of each wafer already subjected to the mirror polishing process is filtered to remove long wavelength components. Moreover, the diagram of the difference in height shown in FIG. 10 is a diagram showing a difference in height of the nanotopography; the height becomes lower as the color becomes darker, the darkest portion is −20 nm from the center height, and the height becomes higher as the color becomes lighter, and the lightest portion is +20 nm from the center height. The difference in height of from the minimum height to the maximum height is 40 nm. Since the nanotopography is measured by fixing any three points on an outer edge of the wafer, the nanotopography map shows a difference in height between the surfaces in a state where the wafer is not adsorbed.

As proved from FIG. 10, there is a relatively large difference in height since a difference of the light and shade of striped pattern are greatly observed the whole of the first surface of the wafer in the Comparative Examples 1 to 6. On the other hand, it is proved that: although the difference of the light and shade of striped pattern are slightly observed at approximately half of the first surface of the wafer, the light and shade of striped pattern are not observed in the remaining approximately half, and therefore the difference in height is relatively small, in the Example 3; and the light and shade of striped pattern are not observed in the whole of the first surface of the wafer and there is almost no difference in height, in Examples 1, 2, and 4.

### <Comparative Test 3 and Evaluation>

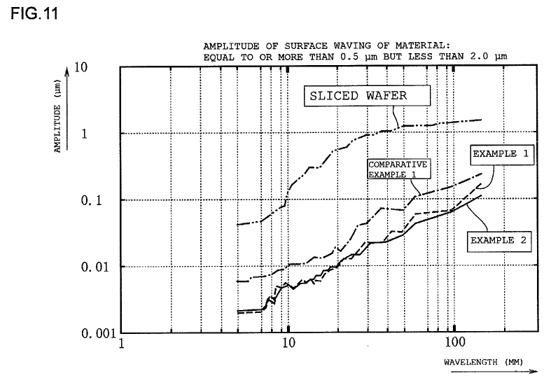

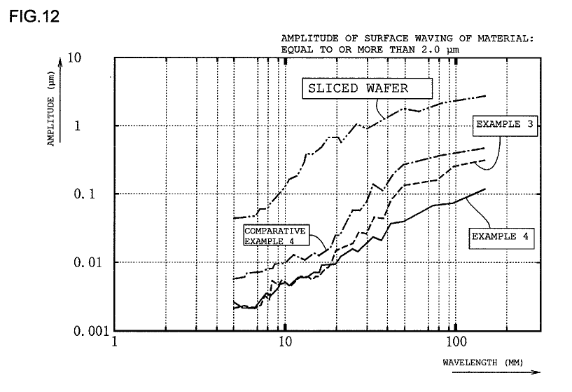

A surface height of each wafer of the Examples 1 to 4 and the Comparative Examples 1 and 4 before applying the mirror polishing process is frequency-analyzed, and an amplitude of the wavelength of the surface waving component is examined. More specifically, the surface height of the wafer is frequency-analyzed using an electrostatic capacity type form measuring apparatus (SBW made by Kobelco Research Institute, Inc.) with respect to each wafer the Examples 1 to 4 and the Comparative Examples 1 and 4 before applying the mirror polishing process. Moreover, a wavelength band region of which a short wavelength period component is less than 10 mm and a long wavelength period component is more than 100 mm is cut off to the surface height measured data of the wafer to be subjected to a bandpass filtering process, and then the amplitude of the wavelength of the surface waving component in a wavelength area of 10 mm to 100 mm is obtained. The results are shown in FIGS. 11 and 12. In addition, FIGS. 11 and 12 respectively show results of the amplitude of the wavelength of the surface waving component in the wavelength area of 10 mm to 100 mm of these sliced wafers obtained by selecting a wafer of which the amplitude of the surface waving of the material is equal to or more than 0.5 μm but is less than 2.0 μm, and a wafer of which the amplitude of the surface waving of the material is equal to or more than 2.0 μm, as sliced wafers among the wafers which are sliced.

As proved from FIG. 11, when using the wafer of which the amplitude of the surface waving of the material is equal to or more than 0.5 μm but is less than 2.0 μm, the amplitude of the wavelength of the surface waving component in the wavelength area of 10 mm to 100 mm exceeds 1 μm at the maximum in the sliced wafer, and the amplitude of the wavelength of the surface waving component in the wavelength area of 10 mm to 100 mm is still large as 0.2 μm at the maximum, in the Comparative Example 1. On the other hand, the amplitude of the wavelength of the surface waving component in the wavelength area of 10 mm to 100 mm can be reduced to equal to or less than 0.1 μm, in the Examples 1 and 2.

As proved from FIG. 12, when using the wafer of which the amplitude of the surface waving of the material is equal to or more than 2.0 μm, the amplitude of the wavelength of the surface waving component in the wavelength area of 10 mm to 100 mm exceeds 2 μm at the maximum in the sliced wafer, and the amplitude of the wavelength of the surface waving component in the wavelength area of 10 mm to 100 mm is still large as 0.4 μm at the maximum, in the Comparative Example 4. On the other hand, the amplitude of the wavelength of the surface waving component in the wavelength area of 10 mm to 100 mm can be reduced to equal to or less than 0.2 μm, in the Example 3, and the amplitude of the wavelength of the surface waving component in the wavelength area of 10 mm to 100 mm can be reduced to equal to or less than 0.1 μm, in the Example 4.

### Comparative Test 4 and Evaluation

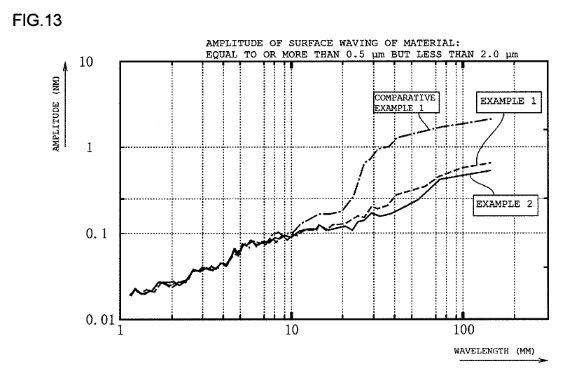

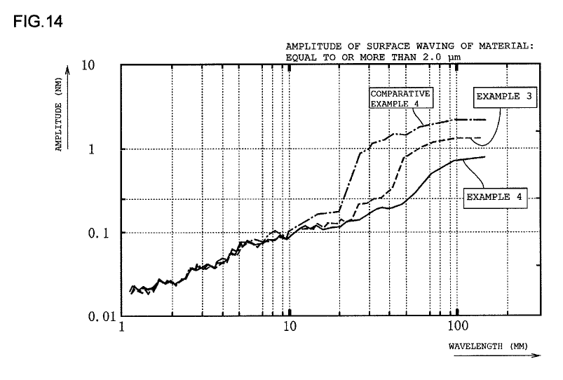

A surface height of each wafer of the Examples 1 to 4 and the Comparative Examples 1 and 4 after applying the mirror polishing process is frequency-analyzed, and an amplitude of the wavelength of the surface waving component is examined. More specifically, in a similar manner to the comparative test 3, the surface height of the wafer is measured and frequency-analyzed using an optical-interference type flatness measuring device (Wafersight2 made by KLA Tencor) with respect to each wafer of the Examples 1 to 4 and the Comparative Examples 1 and 4 after performing the mirror polishing process. Moreover, a wavelength band region of which a short wavelength period component is less than 10 mm and a long wavelength period component is more than 100 mm is cut off to the surface height measured data of the wafer to be subjected to a bandpass filtering process, and then the amplitude of the wavelength of the surface waving component in a wavelength area (10 mm to 100 mm) is obtained. The results are shown in FIGS. 13 and 14.

As proved from FIG. 13, when using the wafer of which the amplitude of the surface waving of the material is equal to or more than 0.5 μm but is less than 2.0 μm, the amplitude of the wavelength of the surface waving component in the wavelength area of 10 mm to 100 mm is still large as 1.8 nm at the maximum, in the Comparative Example 1. On the other hand, the amplitude of the wavelength of the surface waving component in the wavelength area of 10 mm to 100 mm can be reduced to equal to or less than 0.5 nm, in the Examples 1 and 2.

As proved from FIG. 14, when using the wafer of which the amplitude of the surface waving of the material is equal to or more than 2.0 μm, the amplitude of the wavelength of the surface waving component in the wavelength area of 10 mm to 100 mm is still large as 2.1 nm at the maximum, in the Comparative Example 4. On the other hand, the amplitude of the wavelength of the surface waving component in the wavelength area of 10 mm to 100 mm can be reduced to equal to or less than 1.3 nm, in the Example 3, and the amplitude of the wavelength of the surface waving component in the wavelength area of 10 mm to 100 mm can be reduced to equal to or less than 0.6 nm, in the Example 4.

### Reference Example 1

After forming the first coating layer on the first surface of the wafer by performing the coating layer forming step and the coating layer curing step once on the first surface of the wafer, the second surface of the wafer is ground with reference to the first coating layer surface, and the first surface of the wafer is further ground with reference to the second surface, in a similar manner to the Comparative Example 1, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is less than 0.5 μm is selected. This wafer is referred to as the Reference Example 1.

### Reference Example 2

After forming the first and second coating layers on the first surface of the wafer by repeating the coating layer forming step and the coating layer curing step twice, and grinding the second surface of the wafer with reference to the surface of the second coating layer, the first and second coating layers are removed therefrom, and then the first surface of the wafer is ground with reference to the second surface of the wafer, in a similar manner as the Example 1, except that: a surface height of the first surface of the wafer is frequency-analyzed; and the wafer of which the amplitude of surface waving on the first surface of the wafer (amplitude of the surface waving of the material) in the wavelength region of 10 mm to 100 mm is less than 0.5 μm is selected. This wafer is referred to as the Reference Example 2.

### Reference Example 3

A wafer of which both surfaces are ground is obtained in a similar manner to the Reference Example 2, except that the coating layer forming step and the coating layer curing step are repeated 3 times. This wafer is referred to as the Reference Example 3.

### <Comparative Test 5 and Evaluation>

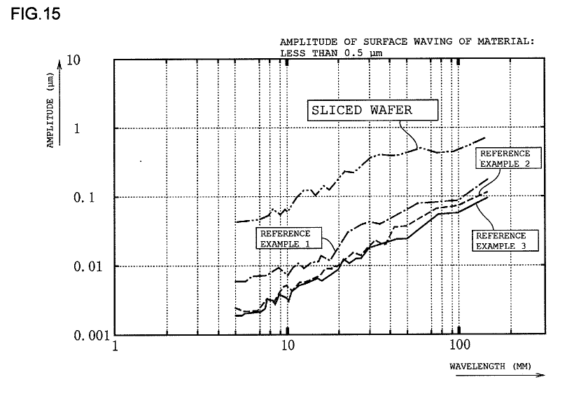

In a similar manner to the comparative test 3, a surface height of each wafer of Reference Examples 1 to 3 before applying the mirror polishing process is frequency-analyzed, and then the amplitude of the wavelength of the surface waving component in the wavelength area of 10 mm to 100 mm is obtained. This result thereof is shown in FIG. 15. In addition, FIG. 15 shows a result of the amplitude of the wavelength of the surface waving component in the wavelength area of 10 mm to 100 mm of the sliced wafer obtained by selecting a wafer of which the amplitude of the surface waving of the material is less than 0.5 μm, as the sliced wafer among the wafers which are sliced.

As proved from FIG. 15, when using the wafer of which the amplitude of the surface waving of the material is less than 0.5 μm, the amplitude of the wavelength of the surface waving component in the wavelength area of 10 mm to 100 mm is increased to almost 1 μm at the maximum in the sliced wafer. On the other hand, the amplitude of the wavelength of the surface waving component in the wavelength area of 10 mm to 100 mm can be reduced to equal to or less than 0.1 μm, in the Reference Examples 1 to 3.

### <Comparative Test 6 and Evaluation>

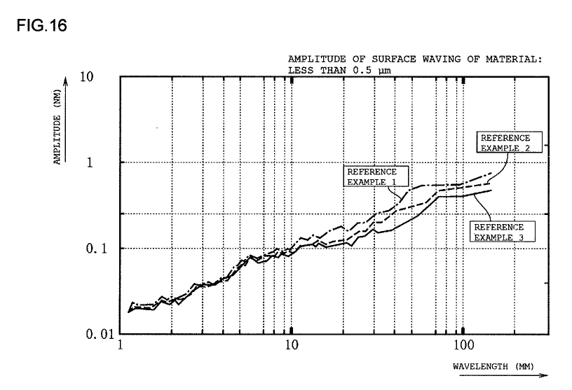

In a similar manner to the comparative test 4, a surface height of each wafer of Reference Examples 1 to 3 after applying the mirror polishing process is frequency-analyzed, and then the amplitude of the wavelength of the surface waving component in the wavelength area of 10 mm to 100 mm is obtained. This result thereof is shown in FIG. 16.

As proved from FIG. 16, when using the wafer of which the amplitude of the surface waving of the material is less than 0.5 μm, the amplitude of the wavelength of the surface waving component in the wavelength area of 10 mm to 100 mm can be reduced to equal to or less than 0.5 nm, in the Reference Examples 1 to 3.

### DESCRIPTION OF THE REFERENCE NUMERALS

10: Semiconductor wafer
11: First surface
11a: Surface waving of a first surface
12: Second surface
14, 16: Curable material
21: First coating layer
22: Second coating layer

1. A processing method of a semiconductor wafer comprising:
slicing a semiconductor single crystal ingot by means of a wire saw device and obtaining a thin disc-like semiconductor wafer;
forming a planarized coating layer by applying a curable material to a whole first surface of the wafer;
curing the coating layer;
mounting the wafer on a table of a grinding apparatus so that a surface of the cured coating layer abuts on a reference surface of the table, and subsequently flatly grinding a second surface on a reverse side of the first surface of the wafer by means of the grinding apparatus;
removing the cured coating layer from the first surface of the wafer; and
mounting the wafer in the table of the grinding apparatus so that the second surface of the wafer from which the coating layer is removed abuts on the reference surface of the table, and subsequently flatly grinding the first surface of the wafer by means of the grinding apparatus, wherein
a surface height of the first surface of the wafer after the slicing and before the coating layer forming is subjected to frequency analysis, and when the amplitude of the surface waving of the first surface of the wafer in a wavelength region of 10 mm to 100 mm is equal to or more than 0.5 μm, the coating layer forming and the coating layer curing are repeated a plurality of times.

2. The processing method of the semiconductor wafer according to claim 1, wherein
the surface height of the first surface of the wafer after the slicing and but before the coating layer forming is frequency-analyzed, and the coating layer forming and the coating layer curing are repeated twice if the amplitude of the surface waving of the first surface of the wafer in the wavelength region of 10 mm to 100 mm is equal to or more than 0.5 μm but is less than 2.0 μm.

3. The processing method of the semiconductor wafer according to claim 1, wherein
the surface height of the first surface of the wafer after the slicing and but before the coating layer forming is frequency-analyzed, and the coating layer forming and the coating layer curing are repeated 3 times if the amplitude of the surface waving of the first surface of the wafer in the wavelength region of 10 mm to 100 mm is equal to or more than 2.0 μm.
